(19) United States
(12) Patent Application Publication
(10) Pub. No.: US 2025/0311450 A1
(43) Pub. Date: Oct. 2, 2025

(54) MANUFACTURING TECHNIQUES FOR MICROLENS ARRAY STRUCTURES

(71) Applicant: Tectus Corporation, Cupertino, CA (US)

(72) Inventor: Brian Elliot Lemoff, Morgan Hill, CA (US)

(21) Appl. No.: 19/083,226

(22) Filed: Mar. 18, 2025

Related U.S. Application Data
(60) Provisional application No. 63/570,658, filed on Mar. 27, 2024.

(51) Int. Cl. H10F 39/00; B29C 33/38

(52) U.S. Cl. CPC H10F 39/024; B29C 33/3842; H10F 39/8063

(57) ABSTRACT

A process for manufacturing microlens arrays includes the following steps. A preform for a microlens array is created. The preform includes an array of first dome shapes corresponding to microlenses in the microlens array. The domes shapes may be different in size and/or shape than the final microlenses to account for subsequent manufacturing steps. Atomic layer deposition is used to deposit a conformal layer on the array of first dome shapes to create an array of second dome shapes. This can be used as a master form for manufacturing the microlens array. For example, the shape of the master may be transferred to a stamp, and the stamp pressed into lens material to create the microlens array.

### CROSS-REFERENCE TO RELATED APPLICATION(S)

This application claims priority under 35 U.S.C. § 119(e) to U.S. Provisional Patent Application Ser. No. 63/570,658, “Microlens array structures and manufacturing techniques,” filed Mar. 27, 2024. The subject matter of all of the foregoing is incorporated herein by reference in its entirety.

### BACKGROUND

### 1. Technical Field

This disclosure relates generally to microlens arrays, and more particularly, to manufacturing microlens arrays.

### 2. Description of Related Art

Ultra-dense micro-LED arrays are the basis of microdisplays featuring very small pixels arranged on a very small pixel pitch. These microdisplays may have pixels as small as 0.9 μm and have as many as 14,000 pixels per inch, for example. Usually, “ultra-dense” means that emitters are smaller than 5 μm and/or the emitter pitch is less than 5 μm. Light emitted by micro-LEDs, and especially light subsequently converted to another color (e.g., in a quantum dot color converter), has a broad angular distribution. It may even approach a Lambertian distribution. What are needed are ways to make maximum use of the emitted light.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 is a schematic top view of a microlens array in which lenses overlap their nearest neighbors, but not their next nearest neighbors.

FIG. 2 is a schematic cross sectional view of the microlens array of FIG. 1 along the dashed line labeled “HORIZONTAL CUT” in FIG. 1.

FIG. 3 is a schematic cross sectional view of the microlens array of FIG. 1 along the dashed line labeled “DIAGONAL CUT” in FIG. 1.

FIG. 4 is a schematic top view of a microlens array in which lenses do not overlap their neighbors.

FIG. 5 is a schematic cross sectional view of the microlens array of FIG. 4 along the dashed line labeled “HORIZONTAL CUT” in FIG. 4.

FIG. 6 is a schematic cross sectional view of the microlens array of FIG. 4 along the dashed line labeled “DIAGONAL CUT” in FIG. 4.

FIG. 7 is a schematic top view of the microlens array of FIG. 4 over which a thin layer of material has been added by, for example, atomic layer deposition.

FIG. 8 is a schematic cross sectional view of the microlens array of FIG. 7 along the dashed line labeled “HORIZONTAL CUT” in FIG. 7.

FIG. 9 is a schematic cross sectional view of the microlens array of FIG. 7 along the dashed line labeled “DIAGONAL CUT” in FIG. 7.

FIG. 10A is a schematic, horizontal cross sectional view of a preform for a microlens array in which the height of the dome shapes is more than half their diameter.

FIG. 10B is a schematic, horizontal cross sectional view of the preform of FIG. 10A over which a thin layer of material has been added by, for example, atomic layer deposition.

FIG. 11A is a schematic, horizontal cross sectional view of a preform for a microlens array in which dome shapes are formed atop pedestals.

FIG. 11B is a schematic, horizontal cross sectional view of the preform of FIG. 11A over which a thin layer of material has been added by, for example, atomic layer deposition.

FIG. 12A is a schematic, cross sectional illustration of a step in a microlens array fabrication process in which photoresist is patterned on a substrate.

FIG. 12B is a schematic, cross sectional illustration of a step in a microlens array fabrication process in which the patterned photoresist of FIG. 12A is reflowed and the resulting shape is transferred to a substrate.

FIG. 12C is a schematic, cross sectional illustration of a microlens array master made by a process involving the steps illustrated in FIGS. 12A and 12B.

FIG. 12D is a schematic, cross sectional illustration of a step in a microlens array fabrication process in which an array master makes an impression in stamp material.

FIG. 12E is a schematic, cross sectional illustration of a step in a microlens array fabrication process in which the stamp of FIG. 12D makes an impression in lens material.

FIG. 12F is a schematic, cross sectional illustration of a microlens array made by a process involving the steps illustrated in FIGS. 12D and 12E.

FIG. 13A is a scanning electron microscope (SEM) top-down image of an array of 4μm diameter microlenses on a 3 μm array pitch.

FIG. 13B is an SEM angled image of the array of FIG. 13A at higher magnification.

FIG. 13C is an SEM cross-section image of the array of FIG. 13B.

FIG. 13D is an enlarged detail of a section of FIG. 13C.

FIG. 14 is a cross sectional view of a section of a microdisplay with a microlens array.

FIG. 15 is a cross sectional view of light emitted from a microdisplay with microlenses.

FIG. 16 is a set of graphs of boost as a function of microlens diameter, for different emitter diameters.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Microlens arrays make micro-LED displays more efficient by compressing emitted light into desirable acceptance angles. Without a microlens, much of the light emitted by a microdisplay pixel may be unusable because it exits the emitter at angles too far away from normal. For example, augmented reality (AR) glasses and goggles need light directed into a specified acceptance angle which may be as narrow as 30 to 40 degrees, full width.

Microlens arrays may be designed such that microlenses do not overlap their neighbors. Alternatively microlens arrays may be designed such that microlenses overlap their nearest neighbors, but not their next nearest neighbors in the array. Finally microlens arrays may be designed such that microlenses overlap their nearest and next nearest neighbors, leaving no areas of the array devoid of lens material.

In certain applications microlenses overlapping nearest, but not next nearest, neighbors provide better performance, in terms of light coupled into a specified acceptance angle, than the other two possibilities just mentioned. See U.S. patent application Ser. No. 18/633,318, “Ultra-dense micro-LED array with partially overlapping microlenses,” filed Apr. 11, 2024, and incorporated herein by reference in its entirety.

Microlens arrays may be made by imprinting curable UV resins on a micro-LED array. After a curable UV resin is applied to a micro-LED wafer, a stamp forms the resin into microlenses. The resin is cured via exposure to ultraviolet light and then the stamp is removed. Alternatively, microlens arrays may be formed by etching and grayscale photoresist techniques. Photoresist reflow may also be useful for forming microlenses which do not touch their neighbors.

Photoresist reflow does not work for making arrays of microlenses which overlap each other. Reflow techniques involve patterning photoresist into small, isolated areas. When the resist is heated, it “reflows” into hemispherical droplets which retain their shape upon cooling. If two droplets touch during the reflow process, they fuse into one, larger droplet. Partially overlapping hemispherical droplets cannot be made with conventional reflow techniques. However, a conventional photoresist reflow technique may be modified as described herein to create microlens arrays in which neighboring lenses touch or overlap.

One way to describe the spacing of microlenses in an array is in terms of lens diameter and array pitch. Array pitch means the distance from a point on a lens to the same point on the neighboring lens. If the diameter of the lenses is less than the array pitch, then the lenses do not touch. In a square array, if the diameter of the lenses is from one to \sqrt{2} times the array pitch, then the lenses overlap their nearest neighbors, but not their next nearest neighbors. If the diameter is greater than \sqrt{2} times the array pitch, then the lenses overlap their nearest and next nearest neighbors. In a square array nearest neighbors lie along the rows and columns of the array, while next nearest neighbors lie along diagonals.

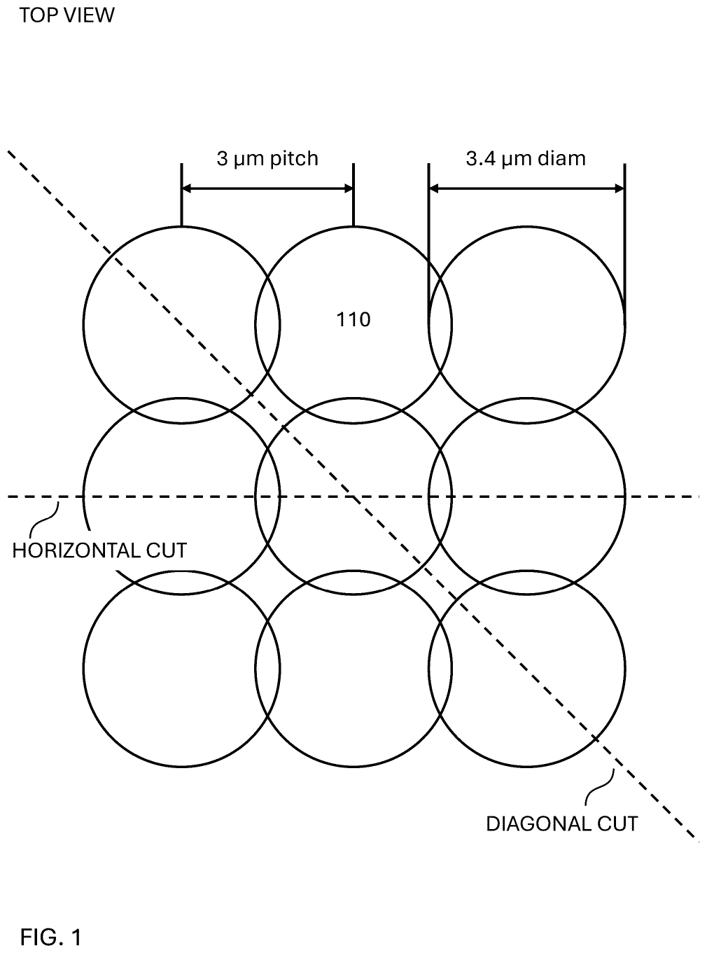

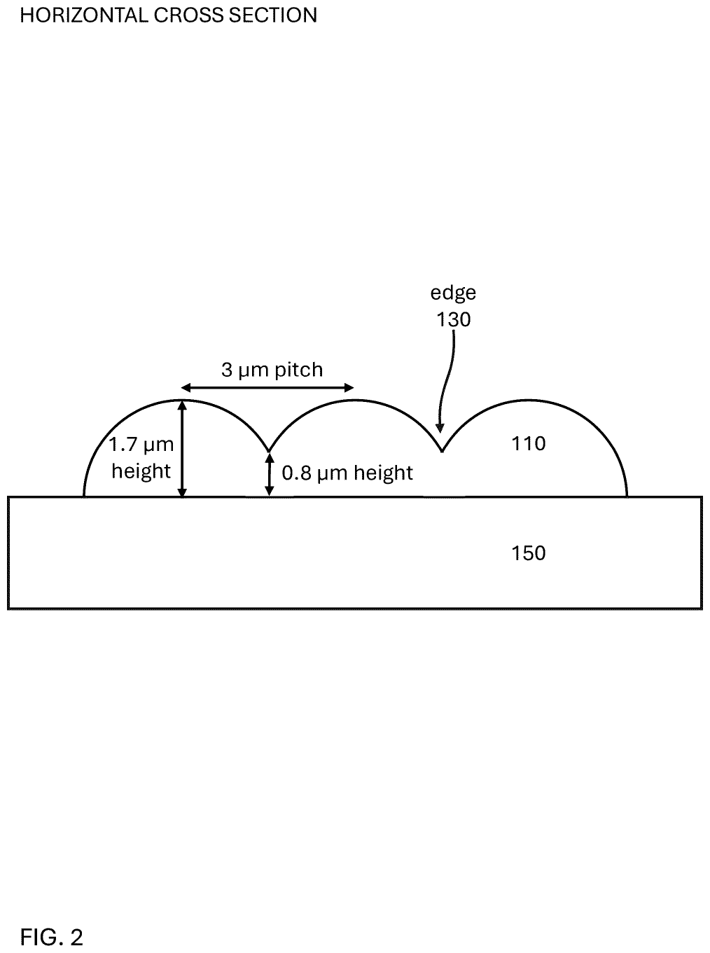

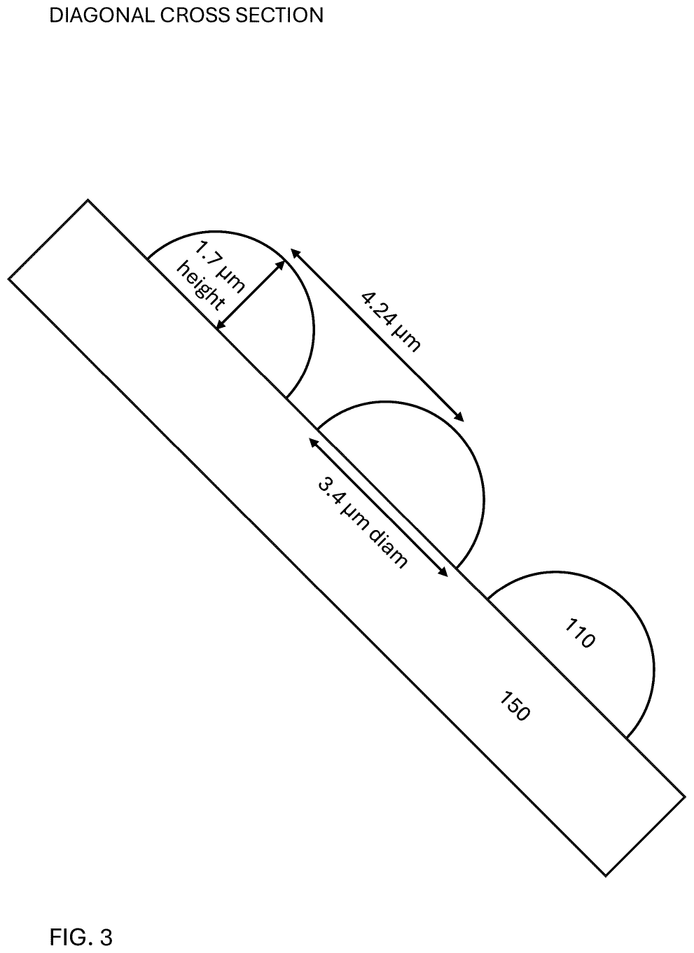

In the examples shown in FIGS. 1-9, the array pitch is 3 μm. The desired diameter of lenses in the array is 3.4 μm which is greater than the array pitch (3 μm) but less than \sqrt{2} times the array pitch (4.24 μm). This situation is shown in FIG. 1 which is a schematic top view of a microlens array in which lenses 110 overlap their nearest neighbors, but not their next nearest neighbors. The dashed lines labeled “HORIZONTAL CUT” and “DIAGONAL CUT” mark planes perpendicular to the page where the figure may be cut to reveal the views shown in FIGS. 2 and 3.

All the figures are schematic. They show dimensions and placement of structures necessary to understand how microlens arrays are designed and made. However, except where noted, they are not photographs or perspective drawings. For example, in FIG. 1, circles represent microlenses 110 and the overlap between neighboring lenses is depicted as an overlap of the circles. The actual boundary between adjacent lenses is a line in the view of FIG. 1. It should be understood that “overlapping” lenses do not actually physically overlap with each other. Rather, they touch at their boundary. See FIGS. 3A-3D of U.S. patent application Ser. No. 18/633,318, “Ultra-dense micro-LED array with partially overlapping microlenses,” filed Apr. 11, 2024, which is incorporated by reference herein.

More insight into the three-dimensional shapes represented by FIG. 1 is provided by cross sectional views in FIGS. 2 and 3. FIG. 2 is a schematic cross sectional view of the microlens array of FIG. 1 along the dashed line labeled “HORIZONTAL CUT” in FIG. 1. The boundary between abutting lenses 110 is a curved line. In FIG. 1, the curved boundary would appear as a straight line, because the curvature lies in a plane perpendicular to the paper. As shown in FIG. 2, there is a discontinuity in the slope of the surface. This discontinuity forms an edge 130 at the boundary between abutting lenses 110. If the lenses are spherical, then the edge 130 is a segment of a circle. Adjacent lenses maintain their hemispheroidal shape right up to the edge where they abut. They do not blend. The sharpness of the internal corner between abutting lenses allows the entire area of a lens to contribute to optical focusing. If the boundary were instead rounded, then the lenses' focusing properties would be distorted in the rounded boundary region.

In FIG. 2, the overlap between nearest neighbor lenses is clear. The lenses 110 are hemispherical. Since their diameter is 3.4 μm, their height above a clear substrate on which they are formed is one-half of 3.4 μm (1.7 μm). The hemispheres are truncated along a dividing line halfway between adjacent lenses. The height of lens material along the dividing line between the lenses is 0.8 μm.

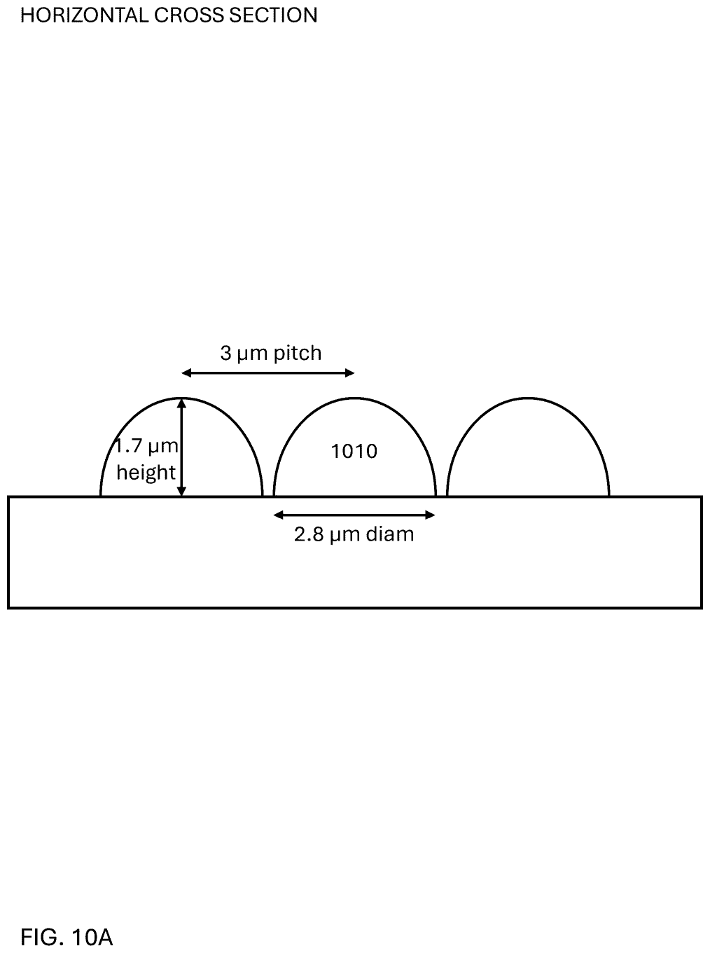

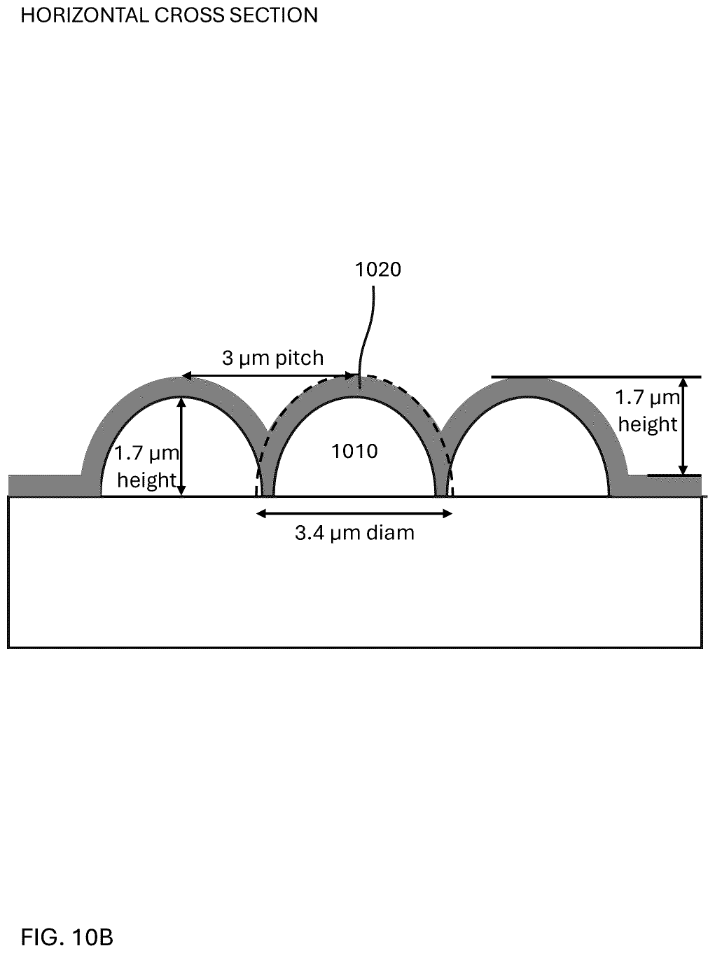

Although the micro-LED emitters are not shown in this view, they are located in a plane that is approximately one lens diameter away from the top of the lenses. That plane is the bottom surface of the rectangular layer 150 shown in the figure. See also FIG. 15 below. (Using the notation of FIG. 10B in U.S. patent application Ser. No. 18/633,318, dimensions “d” and “e” are approximately equal.)

FIG. 3 is a schematic cross sectional view of the microlens array of FIG. 1 along the dashed line labeled “DIAGONAL CUT” in FIG. 1. In this view the space between next nearest neighbor lenses is clear. As before the lenses are hemispherical with height equal to half their diameter. The distance from a point on one lens to the same point on a next nearest neighbor lens (which could be called the “diagonal pitch”) is \sqrt{2} times the 3 μm array pitch, or 4.24 μm.

As mentioned above, microlens arrays designed such that microlenses overlap their nearest neighbors, but not their next nearest neighbors in the array are optimal for coupling light into a specified acceptance angle in certain situations. The array illustrated in FIGS. 1-3 is such an array. Unfortunately a master for this array cannot be made by conventional photoresist reflow techniques because the overlapping hemispheres fuse into each other and lose their hemispherical shape during reflow. Nonetheless reflow is a valuable process because of its high spatial accuracy. The spacing and size of hemispherical lens shapes made via photoresist reflow is controlled with photolithography tools that routinely create patterns with better than 100 nm accuracy. State-of-the-art photolithography may even offer 10 nm accuracy. Furthermore, photolithography tools can maintain their accuracy over distances of several millimeters up to a few centimeters.

A conventional photoresist reflow technique may be modified to create microlens array masters in which neighboring lenses touch or overlap. The modified process involves first creating a photoresist reflow shape array with isolated hemispheres. Next a thin layer of material is grown conformally over the array. The layer grows normal to the surface and fills in spaces between adjacent hemispheres. The result is an array of partially overlapping hemispheres. However, the added layer increases both the diameter of the hemispheres and the height of the substrate between next nearest neighbors. Therefore a little less of the hemispheres' surface is exposed than is shown in FIGS. 1-3.

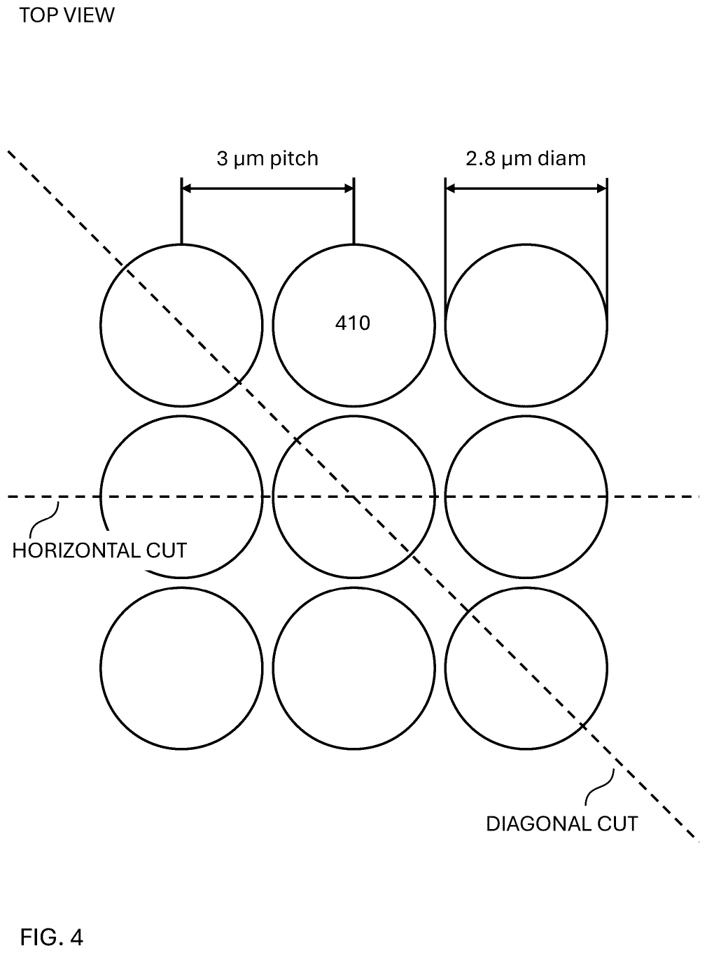

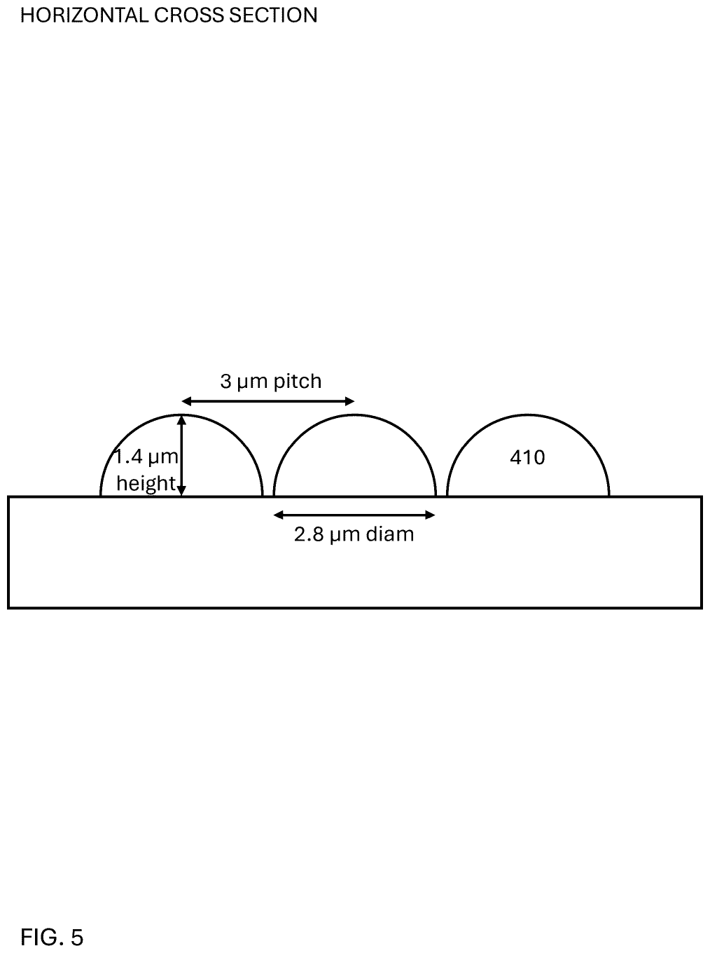

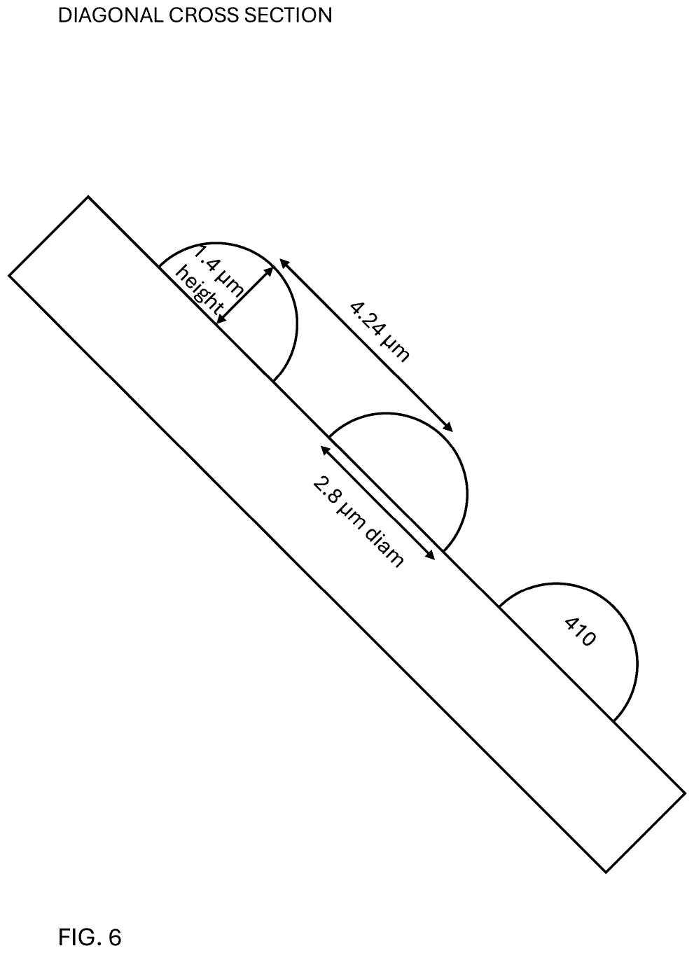

FIGS. 4-6 illustrate a microlens array that can be fabricated with conventional photoresist reflow techniques. FIG. 4 is a schematic top view of a microlens array in which lenses 410 do not overlap their neighbors. The array pitch is 3 μm and the microlens diameter is 2.8 μm. The dashed lines labeled “HORIZONTAL CUT” and “DIAGONAL CUT” mark planes perpendicular to the page where the figure may be cut to reveal the views shown in FIGS. 5 and 6.

FIG. 5 is a schematic cross sectional view of the microlens array of FIG. 4 along the dashed line labeled “HORIZONTAL CUT” in FIG. 4. The lenses 410 are hemispherical. Since their diameter is 2.8 μm, their height above a clear substrate on which they are formed is one-half of 2.8 μm (i.e. 1.4 μm).

FIG. 6 is a schematic cross sectional view of the microlens array of FIG. 4 along the dashed line labeled “DIAGONAL CUT” in FIG. 4. As before the lenses 410 are hemispherical with height equal to half their diameter. The distance from a point on one lens to the same point on a next nearest neighbor lens (which might be called the “diagonal pitch”) is \sqrt{2} times the 3 μm array pitch, or 4.24 μm.

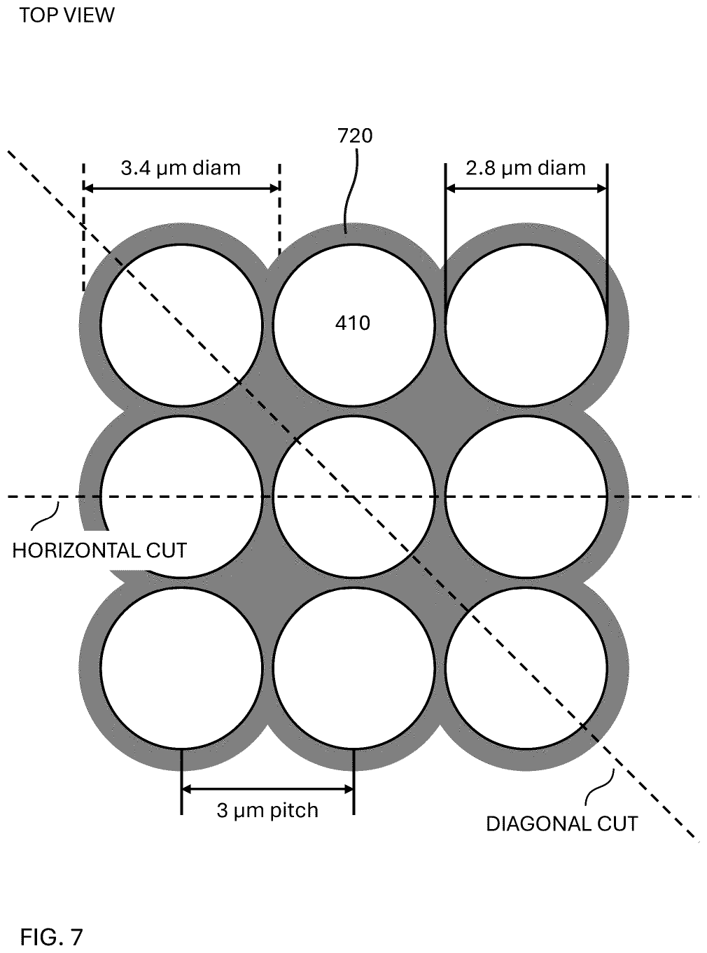

FIGS. 7-9 illustrate the effect of adding a thin, conformal layer over the structures 410 of FIGS. 4-6. In the example of FIGS. 7-9 the thickness of the added layer is 0.3 μm. One way to form the added layer is through atomic layer deposition (ALD) which is a kind of chemical vapor deposition process that can create highly conformal coatings on high-aspect-ratio and complex structures. ALD is based on an alternating sequence of self-limiting surface reactions which build up a layer of solid material with sub nanometer thickness control. Each cycle of alternating reactions deposits one atomic layer. The thickness of the final structure depends on the number of ALD cycles performed. ALD equipment is available from several manufacturers including Beneq, Lam Research, Tokyo Electron, and others. Many different materials may be deposited by ALD including oxides, metals and nitrides. A convenient material for the processes described herein is aluminum oxide, Al₂O₃. Alternatively, the conformal layer may be deposited by sputtering, physical vapor deposition or other forms of chemical vapor deposition.

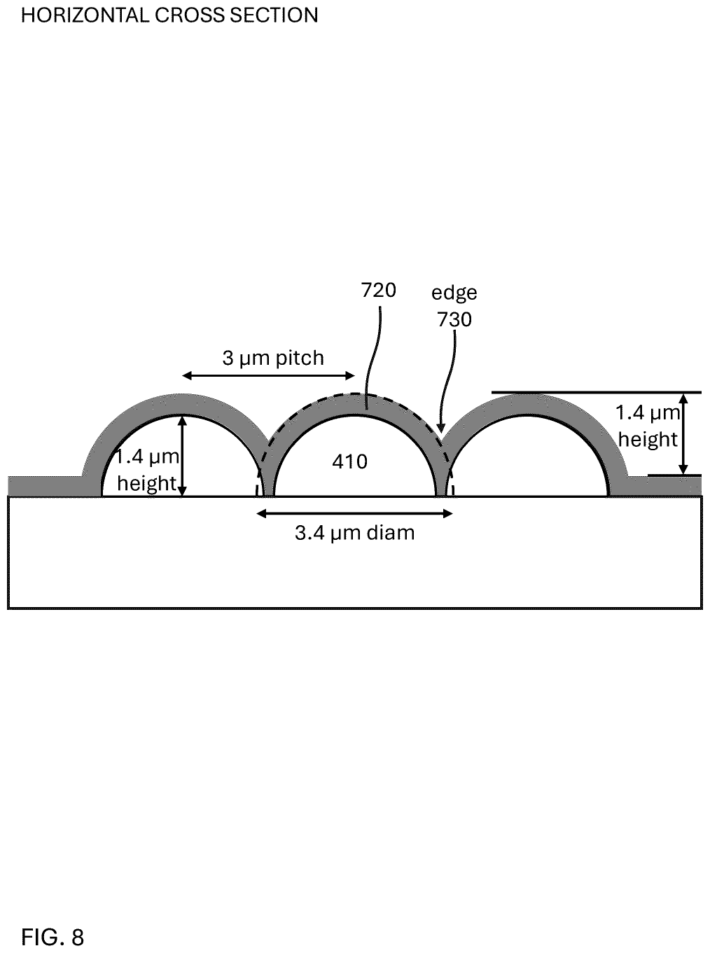

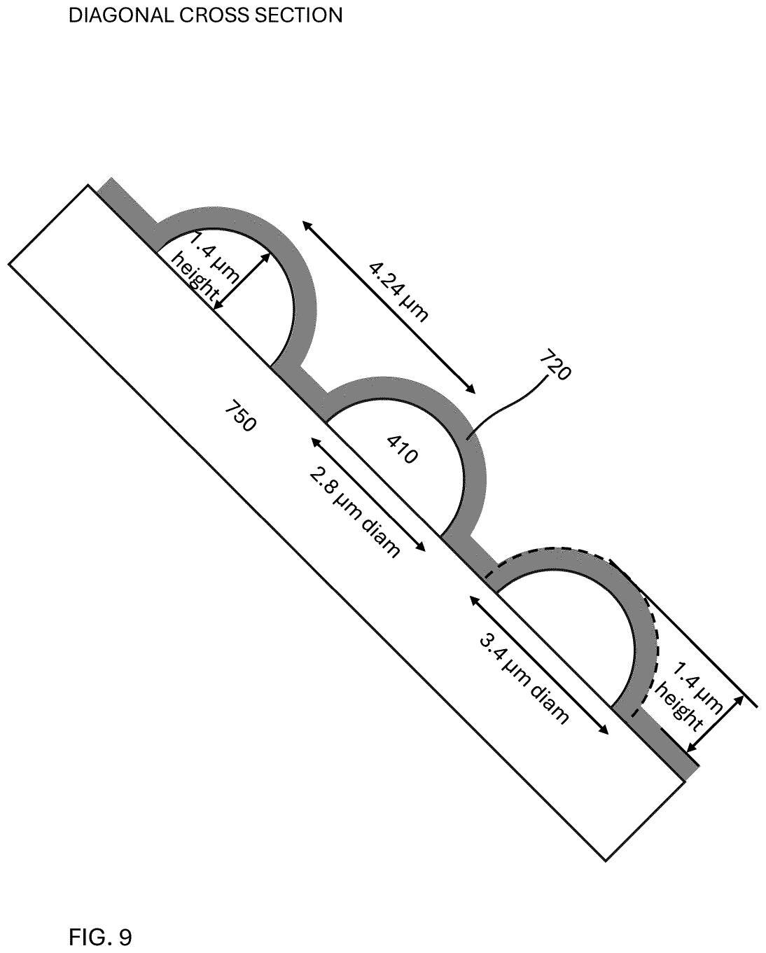

FIG. 7 is a schematic top view of the microlens 410 array of FIG. 4 over which a thin conformal layer of material 720 has been added by, for example, atomic layer deposition. The array pitch is 3 μm. The microlens diameter is 2.8 μm before atomic layer deposition and 3.4 μm afterward. The dashed lines labeled “HORIZONTAL CUT” and “DIAGONAL CUT” mark planes perpendicular to the page where the figure may be cut to reveal the views shown in FIGS. 8 and 9. Note that, for purposes of illustration, added material is illustrated only between hemispheres in FIG. 7. FIGS. 8 and 9 clarify the meaning of the figure.

FIG. 8 is a schematic cross sectional view of the microlens array of FIG. 7 along the dashed line labeled “HORIZONTAL CUT” in FIG. 7. In FIG. 8, both the 3 μm array pitch and the 3.4 μm diameter of the lenses 410 covered with 0.3 μm of deposited material 720 are labeled. The conformally deposited material 720 enlarges the lenses 410 while maintaining their shape. As they grow in size, adjacent lenses 410 may touch (abut) each other and, as more material 720 is deposited, an edge 730 is created between abutting lenses 410. The height of the lens with and without deposited material is the same (1.4 μm) because the deposited material coats both the lens and any flat areas of the substrate between lenses.

This effect is more easily seen in FIG. 9 which is a schematic cross sectional view of the microlens array of FIG. 7 along the dashed line labeled “DIAGONAL CUT” in FIG. 7. The 0.3 μm layer of deposited material 720 covers the lenses 410, increasing their diameter to 3.4 μm, and the substrate, thus preserving the lens height at 1.4 μm above the substrate. The shape that is desired, however, is hemispherical and protruding 1.7 μm above the substrate 750, with an edge 730 formed at the boundary between abutting microlenses. The edge 730 between lenses indicates that the lenses extend to the boundary. This increases the effective area and fill factor of the lens. If the boundaries were rounded instead, then some useful lens area would be sacrificed.

In the processes shown in FIGS. 1-9, the shapes are described as spherical or spheroidal, but they do not have to be exactly these geometrical shapes. More generally, they will be referred to as dome-shaped. This includes other smooth, convex shapes, even if they are not strictly spheroidal. Examples include parabolic, either end of an egg shape, and aspheric.

In addition, every dome shape in FIGS. 1-9 is referred to as a microlens for convenience. However, in some fabrication processes, the dome shapes may not be the final microlenses. They may be master forms or other precursors, which are then used to create the microlens array through stamping or other processes. For example, consider a situation where the process of FIGS. 7-9 is used to create a master, rather than the final microlens array. In that case, none of the dome shapes shown in FIGS. 7-9 are the final microlens. Rather, the original array of “microlenses” 410 may be referred to as a precursor form or preform for the desired microlens array, since it is a precursor to the final form. The conformal layer 720 is deposited on the preform domes 410. The “microlens after ALD,” which is a combination of the preform dome 410 and conformal layer 720 is then the master form. There may also be a chain of masters. For example, there may be an intermediate master which is a positive version of the final desired product. The intermediate master is used to make one or more working masters which are a negative version of the final desired product. The working master(s) are used to stamp the final products.

The dome shapes 410 are not touching in the preform but they are abutting in the master form due to the conformal layer. The master form has an edge 730 between adjacent dome shapes, created by the conformal layer. Thus, the conformal layer is thick enough so that adjacent dome shapes grow large enough to touch each other, thus forming an edge at the boundary between abutting shapes. In addition, a thinner conformal layer may be preferred since that may reduce processing time and add less stress to the wafer. In one approach, the preform domes 410 made by photoresist reflow are almost touching, so that the conformal layer 720 can be thinner while still forming the desired edge 730. For microlenses on a 5 μm or smaller pitch (area of 25 μm² or less per microlens), the conformal layer may be 1 μm or less or even 0.5 μm or less. In relative terms, the thickness of the conformal layer may be not more than 50% of a width of the preform domes.

This master form can then be used to create a stamp or otherwise transferred to the final lens material to create the microlens array. In some cases, the master may be used multiple times to create many stamps. In other cases, the master may be a single-use master, which can be used only once to create only a single stamp.

The dome shapes 410 in the preform may be created using a photoresist reflow process. Other processes may also be used, for example direct write grayscale lithography. In addition, the dome shapes in the preform and the master form may not be the same as the final microlens shape, in order to account for changes in shape resulting from various steps in the manufacturing processes. For example, if the final microlenses are spherical, the dome shapes in the preform and master form may be spheroidal but not exactly spherical.

FIGS. 10A and 10B illustrate a technique for producing a master form for manufacturing a microlens array (aka, an array master), in which the microlenses have hemispherical, partially overlapping shapes. As discussed below, an array master may be made by transferring the three-dimensional topography of reflowed photoresist to an underlying substrate by etching. Later in the manufacturing process a stamp created from the master transfers lens shapes to lens material, such as a UV curable resin.

The lens material may shrink as much as 20% to 30% in the direction perpendicular to the substrate during curing. Shrinkage flattens hemispherical shapes into oblate spheroids. Therefore, during etching to create a master, etch parameters may be adjusted to create an array of prolate spheroids in the master rather than hemispheres. For example, consider a small area of patterned photoresist which has been reflowed into a hemisphere situated on an underlying substrate. An etch process that removes the substrate faster than it removes the photoresist produces lens shapes that are taller than hemispheres; i.e. prolate spheroids. Later, lens material shrinkage transforms the prolate spheroids back to hemispheres. More generally, if transferring the shape of the master to the lens material changes the transferred shape, the master may be predistorted to compensate for this shape change.

FIG. 10A is a schematic, horizontal cross sectional view of a preform for a microlens array in which the height of the dome shapes 1010 is more than half their diameter. These shapes are prolate spheroids, which are taller than hemispheres. In FIG. 10A, the height (1.7 μm) of each spheroid is greater than half its diameter (2.8 μm).

FIG. 10B is a schematic, horizontal cross sectional view of the preform of FIG. 10A over which a thin layer of material 1020 has been added by, for example, atomic layer deposition. The resulting shape is also a prolate spheroid, although not the same prolate spheroid as shape 1010. These shapes will become hemispherical after shrinkage of lens material later in the manufacturing process.

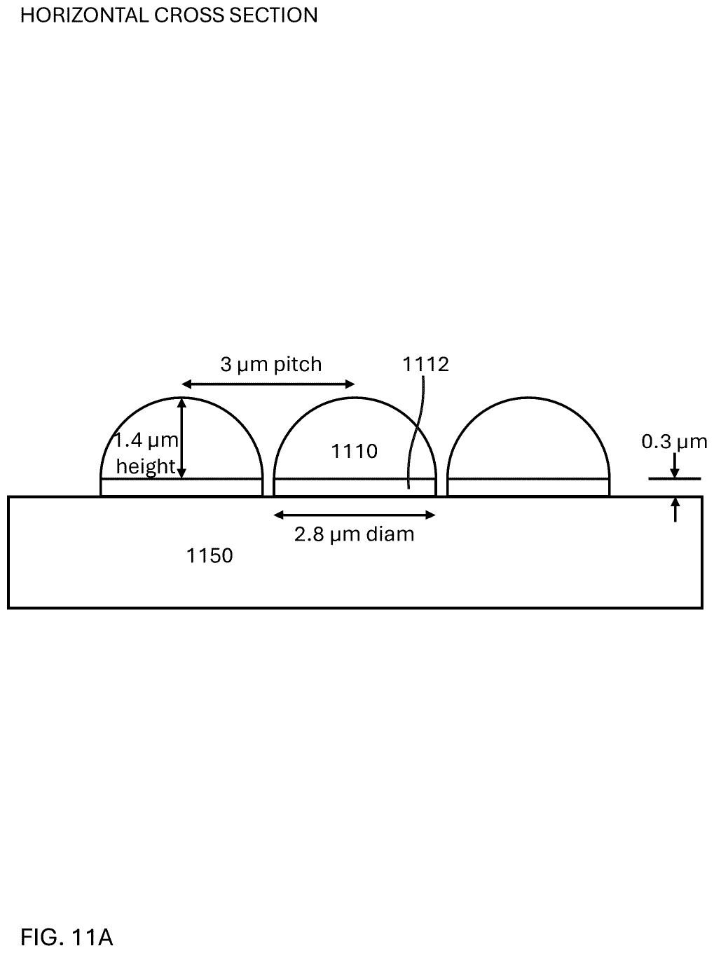

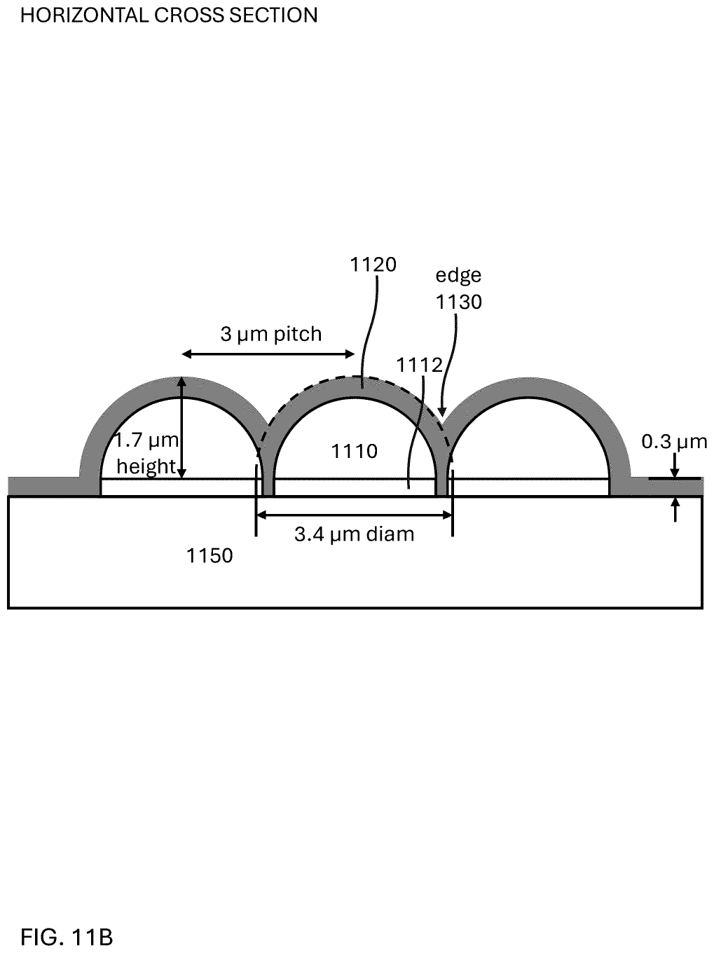

FIGS. 11A and 11B illustrate another technique for producing an array master with hemispherical, partially overlapping shapes. In FIGS. 7-9, adding an ALD layer to an array of hemispheres preserves their shapes, but leaves less of the hemisphere exposed. If the added layer is made thicker and thicker, eventually the hemispherical shapes disappear under the snow drifts of added material. This is a different and separate issue from the distortions caused by lens material shrinkage.

In the technique illustrated in FIGS. 11A and 11B, reflow is used to form hemispherical shapes 1110 on pedestals 1112 rather than on a flat substrate 1150. The technique works for layers added by processes, such as ALD, which grow material normal to the surface to which they are applied, with high-fidelity internal corners. As before, what is desired is 3.4 μm diameter hemispheres on 3.0 μm pitch. To make such a structure, one may first start with a substrate 1150 on which pedestals 1112 are formed, e.g. via photolithography and etching. Alternatively, the dome shapes 1110 may be created first, and then the substrate 1150 is etched to form the pedestals 1112. The pedestals 1112 are cylindrical, 0.3 μm thick (same as the ALD thickness), 2.8 μm diameter, and placed on 3.0 μm pitch. Thus the pedestals do not touch each other. Next, 2.8 μm diameter, hemispherical reflow domes 1110 are formed atop the pedestals. Finally, as shown in FIG. 11B, a 0.3 μm thick ALD layer 1120 is grown on the structure. ALD grows normal to the surface and forms sharp internal corners. The result is the desired structure.

In general, to make hemispheres of diameter D on pitch P<D, one may start with a substrate on which cylindrical pedestals are formed. The pedestals have diameter D−2T and thickness T, and are placed on pitch P. The pedestals do not touch each other; i.e. P>D−2T. (Combining inequalities, D−2T<P<D where P may be in the range from about 1 μm to about 5 μm.) Hemispherical, reflow dome shapes of diameter D−2T are formed on the pedestals. Finally an ALD layer of thickness T is grown. The result is partially overlapping hemispheres of diameter D. The boundary where hemispheres touch forms an edge 1130 because ALD grows normal to surfaces. Pedestals may be formed on a substrate via photolithography and etching.

FIG. 11A is a schematic, horizontal cross sectional view of a preform for a microlens array in which reflow hemispheres 1110 are formed atop cylindrical pedestals 1112. In this example, D=3.4 μm, T=0.3 μm, D−2T=2.8 μm, and P=3 μm.

FIG. 11B is a schematic, horizontal cross sectional view of the preform of FIG. 11A over which a thin layer of material 1120 has been added by, for example, atomic layer deposition. The result is partially overlapping hemispheres formed from the underlying hemispheres 1110 on pedestals 1112, overcoated with an ALD layer 1120. This is the desired structure shown in FIG. 2. Similarly, a diagonal cut through a square array made by the procedure described above, reveals the desired structure shown in FIG. 3.

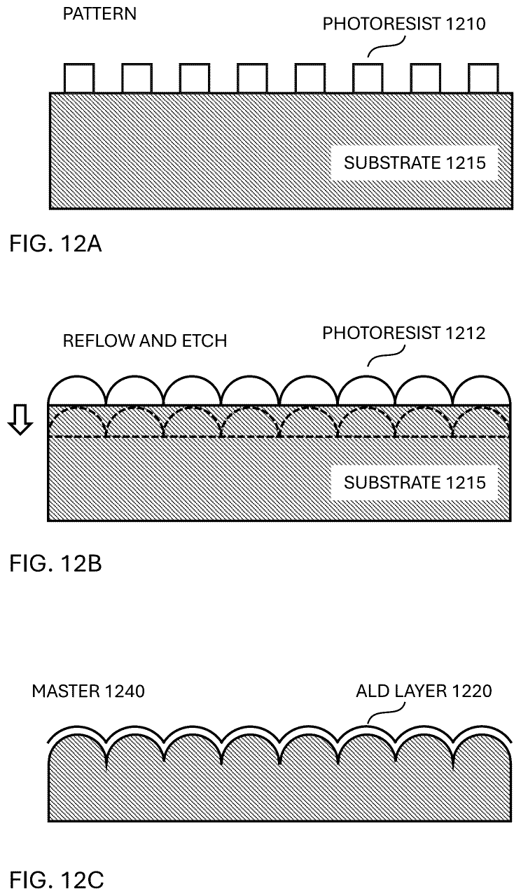

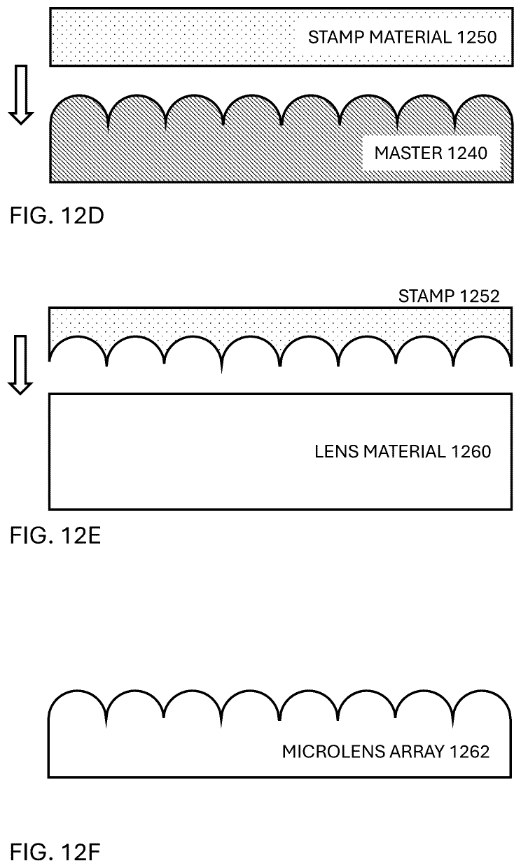

As described below (in connection with FIGS. 12A-12F) the processes described above may be used to create a master and then a stamp in a stamping process for microlens arrays. The stamp creates microlenses in a malleable lens material such as transparent, ultraviolet-light-curable resin. During the creation of the stamp from the master, there is some shrinkage in the vertical direction; i.e. the direction of the arrows in FIGS. 12D and 12E. There is similarly vertical shrinkage during the creation of lens arrays from a stamp. The accumulated vertical shrinkage over the two steps may be as much as about 20% to 30%. Therefore, to create hemispherical lenses, the corresponding lens shapes on a master or other preforms may be prolate spheroids, elongated in the vertical direction. Shrinking an appropriately designed prolate hemispheroid produces a hemisphere.

Preforms may be made using processes other than photoresist reflow. For example, a preform may be made starting with gray scale photolithography. The preform shapes may then be enlarged by growing an ALD layer over them, creating edges between abutting shapes. Gray scale photolithography has a resolution limit or maximum spatial frequency that it can achieve. It can be used to make low-spatial-frequency structures such as overlapping dome shapes with rounded boundaries or non-overlapping dome shapes. The resolution limit may turn a desired, sharp edge at the boundary between one shape and its neighbor into an undesired rounded boundary. The boundary may take the form of a rounded trough or other boundary of continuous slope, rather than an edge with a slope discontinuity. Edges may be obtained by depositing a conformal layer on top of a low spatial frequency preform. Even though overlapping shapes may be possible to make directly with gray scale photolithography, later growing an ALD layer to create an edge between abutting shapes may offer better performance because internal corners in ALD layers may be atomically sharp.

Said another way, gray scale lithography may not be able to create shapes which have discontinuous surface slope. A slope discontinuity, like an edge, is a high spatial frequency feature. The resolution of gray scale lithography may be insufficient to make such a feature. However, an ALD layer grown over separated, smooth features of differing slope, or grown over overlapping smooth features that abut at a smooth boundary, does lead to an atomically sharp, slope discontinuity in the final structure. Thus, growing an ALD layer over preform shapes may serve more than one purpose. It solves the problem of not being able to make reflow lenses that touch, and it also solves the problem of limited gray scale lithography resolution rounding out desired sharp corners at the boundary between abutting shapes.

Once an array master is made, it is used to make microlens arrays that are placed or formed on microdisplays. The master and the microlens arrays have the same microscale topography. A process for making microlens arrays is illustrated in FIGS. 12A-12F.

One process begins with creating photoresist reflow hemispheres. The resulting shape is transferred into a substrate by etching to make a master. A conformal layer is then deposited by atomic layer deposition. Next a stamp is created from the master. Finally the stamp shapes lens material into a microlens array.

FIG. 12A is a schematic, cross sectional illustration of a step in a microlens array fabrication process in which photoresist 1210 is patterned on a master substrate 1215. In a typical process the photoresist is patterned into cylinders with diameter comparable to the thickness of the photoresist. In an ultra-dense array, the diameter of the cylinders may be in the range from about 0.5 μm to about 5.0 μm.

FIG. 12B is a schematic, cross sectional illustration of a step in a microlens array fabrication process in which the patterned photoresist 1212 of FIG. 12A is reflowed and the resulting shape is etched into substrate 1215. For example, this may transfer shapes from the photoresist 1212 to a material such as silicon dioxide. If the etch rate of the silicon dioxide is faster than the etch rate of the resist, the shape etched into the substrate is elongated in the etch direction. If the etch rate of the substrate is slower than the etch rate of the resist, the shape etched into the substrate is shortened in the etch direction. A second process begins with creating cylindrical pedestals and creating reflow hemispheres atop them. For convenience, adjacent shapes are shown as touching in FIG. 12B (and FIG. 12C), but they may be separated as shown in the previous figures.

An ALD layer 1220 is next grown on top as shown in FIG. 12C. The resulting structure may be used as a master 1240. Other alternatives include creating prolate spheroids on the pedestals or non-reflow hemispheres on the pedestals.

FIG. 12C is a schematic, cross sectional illustration of a microlens array master 1240 made by a process involving the steps illustrated in FIGS. 12A-12C. Such arrays may include anywhere from tens of thousands to tens of millions of microlenses. The diameter of each microlens may be in the range from about 0.5 μm to about 5.0 μm.

FIG. 12D is a schematic, cross sectional illustration of a step in a microlens array fabrication process in which an array master 1240 makes an impression in stamp material 1250.

FIG. 12E is a schematic, cross sectional illustration of a step in a microlens array fabrication process in which the stamp 1252 created in FIG. 12D makes an impression in lens material 1260. In both FIGS. 12D and 12E, the stamp material 1250 (or lens material 1260) may be a liquid or other viscous material, and the impression may be made by solidifying the liquid while it is in contact with the master 1240 (or stamp 1252). For example, the lens material may be a transparent, ultraviolet-light-curable resin.

FIG. 12F is a schematic, cross sectional illustration of a microlens array 1262 made by a process involving the steps illustrated in FIGS. 12D and 12E. Such an array, containing thousands to millions of lenses, may have an overall length and width in the range from about 0.5 mm to about 5.0 mm.

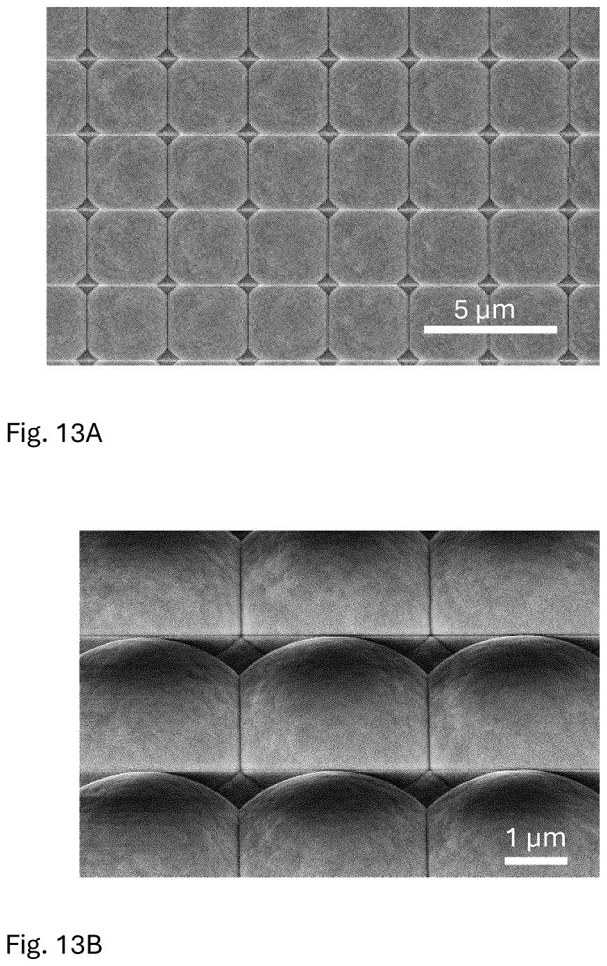

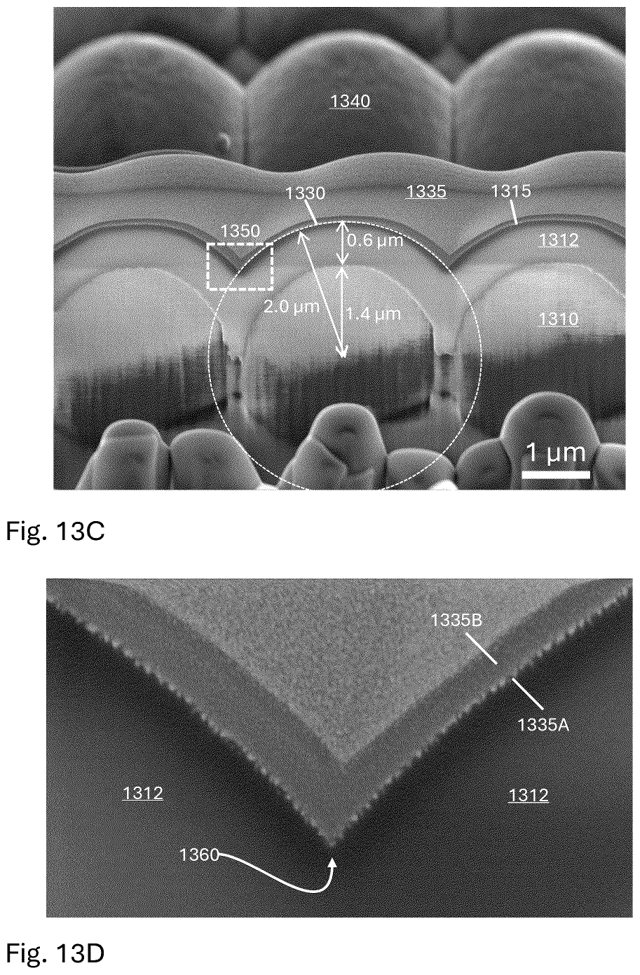

A microlens array master was created using the reflow and atomic layer deposition techniques described herein. FIGS. 13A-13D offer a series of views of the master at increasing magnification.

In the master, an array of 4 μm diameter microlenses was created on a 3 μm array pitch as shown in FIG. 13A. These structures are not the final microlenses, but they will be referred to as microlenses for convenience. The lenses abut their nearest neighbors but not their next nearest neighbors. The lenses do not extend all the way diagonally to the corners of each pixel. The fill factor is less than 100%. Horizontal lines in the figure are an SEM scan artifact. The scale bar in the image is 5 μm long.

FIG. 13B is an SEM angled image of the array of FIG. 13A at higher magnification. Dark, horizontal bands between lenses are an SEM scan artifact. The scale bar in the image is 1 μm long.

FIG. 13C is an SEM cross-section image of the array of FIG. 13B. The scale bar in the lower, right corner of the image is 1 μm long. The foreground of the figure shows a focused ion beam (FIB) cut through a row of three microlenses, exposing the cross section of the lenses. Another row of three microlenses 1340 are visible in the background. The foreground cross section shows a 1.4 μm radius SiO₂ preform dome 1310, and a 0.6 μm thick Al₂O₃ layer 1312 grown by atomic layer deposition. The line 1315 is the surface of the microlens cross section.

The radius of the microlenses (preform dome plus ALD layer) is 2.0 μm, as desired. The lens surfaces 1315 fit a 4-μm-diameter sphere as indicated by 4-μm-diameter circle 1330. Extra metal 1335 (Au/Pt) has been deposited to facilitate the FIB cut and subsequent SEM imaging. Dashed rectangle 1350 indicates the approximate extent of FIG. 13D.

FIG. 13D is an enlarged detail of area 1350 of FIG. 13C. The entire width of the image is about 1 μm. In this view, the edge 1360 at the boundary between adjacent lenses 1312 is apparent. A 10 nm layer 1335A of Au and a thicker layer 1335B of Pt were deposited on the lens surfaces to facilitate the FIB cut and subsequent SEM imaging.

Now consider the use of microlens arrays in micro-LED displays. In micro-LED displays, uniformly-sized emitters may be arranged on an evenly spaced, rectangular grid. Examples of emitters include a micro-LED alone, or a combination of a micro-LED and a color converter. The color converter may be based on quantum dots or other quantum confined nanostructures. Each emitter is served by a corresponding microlens. The microlenses may overlap so that there are no areas of the display devoid of microlenses. Alternatively, optical performance may be increased by using smaller microlenses that partially overlap with each other but which do not cover the entire area of the display (less than 100% fill factor).

The small size (e.g. 0.5-2.0 μm) of the emitters in some displays enables the new kinds of microlens arrays described here. If the emitters were not so small, then designs in which the size of the microlens is different from conventional would not produce displays with high enough resolution for many applications, or the display would be too large to fit in AR glasses and other applications.

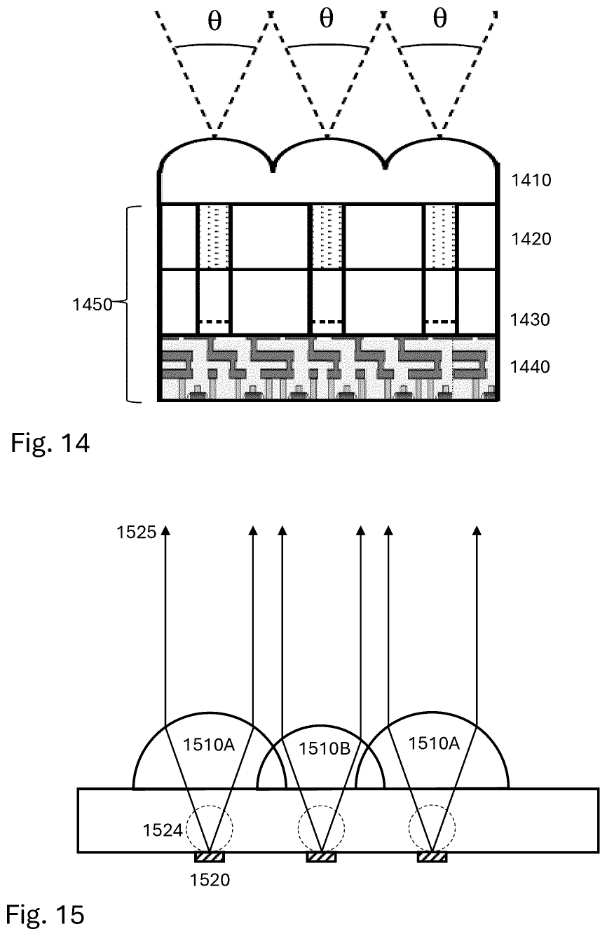

FIG. 14 is a cross sectional view of a section from a microdisplay with microlenses. The microlens array 1410 includes small, clear sections of lenses (e.g., spheres) arranged in a regular pattern. In FIG. 14 the microlenses have spherical curvature and the microlenses are abutting but not all of the display area is covered by microlenses. In other designs, the microlenses may have different shapes and curvatures. In real displays there may be several million microlenses and emitters or more, depending on how many pixels the display has. For example, 4K UHD resolution has 3840×2160 (8,294,400) color pixels, each of which may have red, green and blue emitters, each with its own microlens. For some applications, there may also be far fewer microlenses and emitters, for example 13,000 of each in low resolution monochrome displays. Microlenses may be made of plastic or glass. For some displays, the pixels may have a size in the range from about 0.5 μm to about 5.0 μm, and the size of the display may be in the range from about 0.5 mm to about 5.0 mm.

FIG. 14 shows a microlens array 1410 and a semiconductor die 1450 with the emitters and driver circuitry. From bottom to top, the semiconductor die 1450 includes driver circuitry 1440, micro-LEDs 1430 and quantum dot color conversion materials 1420. In this example, the micro-LEDs 1430 are all the same color. They may be gallium nitride LEDs. The color conversion materials 1420 convert the light from the micro-LEDs 1430 to different colors. The micro-LEDs 1430 and color conversion materials 1420 form the emitters of FIG. 14. The different color emitters may be arranged into color pixels. The driver circuitry 1440 controls the brightness of individual micro-LEDs, which in turn controls the brightness and color of each color pixel. There is one microlens 1410 for each emitter. The microlens collects light from the emitter and couples it into the acceptance cone (full angle θ) for the rest of the system. The bottom of the microlens array layer may be approximately one lens diameter away from the top of the layer.

The microlens array of the display of FIG. 14 may be made by stamping processes as described above. Alternatively the microlens array may be made without stamping. For example, a flat layer of transparent lens material may be deposited on, or attached to, the QD color conversion layer. The lens layer may then be shaped into non-overlapping microlenses with gray scale lithography. Finally, a transparent layer may be grown on the microlenses by ALD. This conformal layer may make the lenses partially overlap. The boundary where the lenses overlap may be atomically sharp as described above.

FIG. 15 shows the effect of microlenses on light collection. The emitters are represented as flat two-dimensional areas, sometimes marked by diagonal cross-hatching. FIG. 15 shows three emitters 1520. Light is emitted over a wide range of angles as suggested by the schematic intensity polar diagrams 1524 in the figure. The radiation pattern may approach a Lambertian distribution in some cases. If light emitted from the display is coupled into a downstream optical system (e.g. projection optics), then any light that propagates outside the acceptance cone of the downstream optics is lost. Lost light reduces the overall efficiency of the system which can be a major concern for battery operated displays. A 10% increase in efficiency gives 10% longer battery life, all other things being equal.

In FIG. 15, the microlenses 1510A,B collimate the emitted light into a narrower range of angles, as indicated by rays 1525, so that more light falls within the acceptance cone of any downstream optical systems. In FIG. 15, different microlenses 1510A and 1510B are used for different emitters. The conformal coating approach described above may also be used to create microlenses 1510A,B of different shapes and/or sizes, by using different preform shapes for the different lenses.

The improvement in system performance with microlenses versus without microlenses may be quantified as the “boost” of the microlens array. The “boost” of a microlens array is defined as the ratio of (a) the optical power coupled into a specified acceptance cone by emitters in a microdisplay with the microlens array to (b) the power coupled into the same acceptance cone without the microlens array.

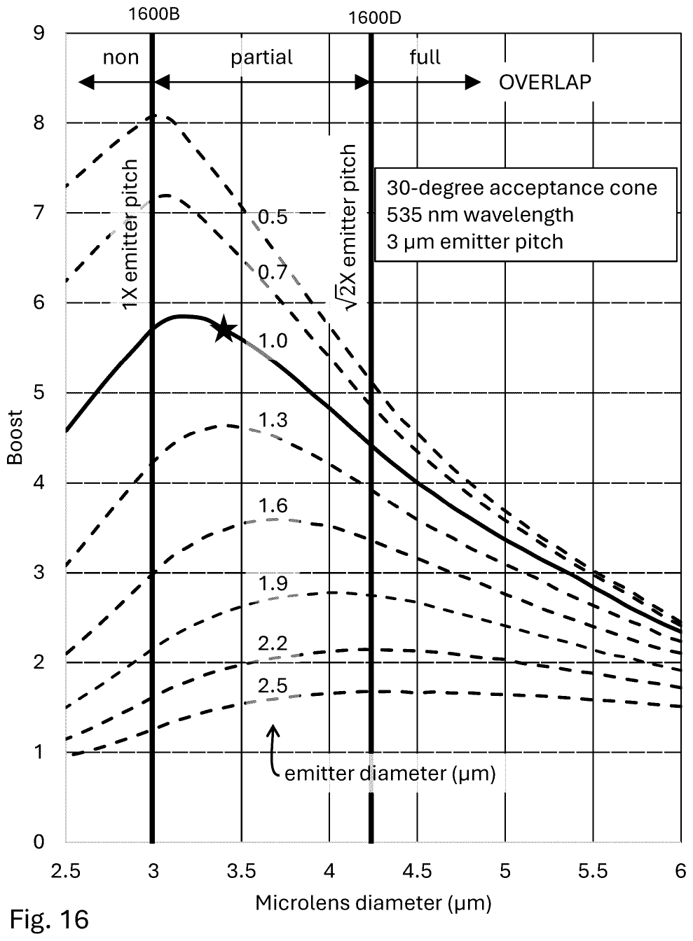

FIG. 16 is a set of graphs of boost as a function of microlens diameter, for different emitter diameters. The emitter diameters range from 0.5 μm to 2.5 μm. These graphs use a 3 μm emitter pitch, 30 degree acceptance cone and 535 nm wavelength. Consider the solid curve in FIG. 16 which represents boost versus microlens diameter for a 1.0 μm diameter emitter. On this curve, the parameters marked by the star are 1 μm emitter diameter, 3 μm emitter pitch and 3.4 μm lens diameter. The boost for this situation is roughly 5.7 and is near the optimum or peak of the curve. A microlens diameter of 3.2 μm would give slightly higher boost. A 3.4 μm microlens diameter has maximum boost for a 1.3 μm emitter diameter.

The vertical line 1600B labeled “1× emitter pitch” corresponds to a non-overlapping situation, where nearest neighbor microlenses just touch each other at a single point, but do not overlap enough to create a longer border. When the microlens diameter is less than the emitter pitch, the microlenses do not touch and there is a gap between them. This region is labeled “non” for “non-overlapping.” The vertical line 1600D labeled “\sqrt{2}x emitter pitch” corresponds to a fully overlapping situation, where the microlenses cover the entire area of the array (100% fill factor). The region to the right of this line is labeled “full” for “fully overlapping.” The region between the “1×” vertical line 1600B and the “\sqrt{2}x” vertical line 1600D is labeled “partial”, corresponding to a partially overlapping situation. There is some overlap of microlenses, but the microlenses do not cover the entire area of the array.

Some trends are apparent from FIG. 16. First, the maximum boost is generally achieved for microlens diameters between 1 and \sqrt{2} times the emitter pitch. For hemispherical lenses, the radius of curvature would be between ½ and \sqrt{2}/2 times the emitter pitch. In this partially overlapping region, microlenses overlap their nearest (row, column) neighbors but not their next nearest (diagonal) neighbors for square arrays. Second, for small emitters (e.g. emitter diameter <0.2 times emitter pitch, or emitter diameter 21 0.6 μm in FIG. 16) maximum boost is achieved when the microlens diameter is approximately equal to the emitter pitch, or the radius of curvature is approximately equal to emitter pitch/2. Third, for medium size emitters (e.g. 0.2 times emitter pitch<emitter diameter<0.5 times emitter pitch, or 0.6 μm<emitter diameter<1.5 μm in FIG. 16) maximum boost is achieved when the microlens diameter is a little larger than the emitter pitch (e.g. 1 times emitter pitch<microlens diameter<1.2 times emitter pitch), or the radius of curvature is a little larger than the emitter pitch/2. This is the partially overlapping region. Fourth, for large emitters (e.g. 0.5 times emitter pitch<emitter size<1 times emitter pitch, or 1.5 μm<emitter diameter<3.0 μm in FIG. 16) maximum boost is achieved when the microlens diameter and radius of curvature remains in the “partially overlapping” region. However, as the microlens diameter approaches the “fully overlapping” region (\sqrt{2} times emitter pitch), the boost curve flattens and boost decreases slowly in the “fully overlapping” region.

FIG. 16 assumes a 30 degree, full angle, acceptance cone for emitted light. The trends noted above remain the same for a 40 degree acceptance cone, but the boost values are less. For the center row (0.2<emitter diameter<0.5), the lens diameter is between 1× and 1.2× the emitter pitch. At these values, the lenses will cover between 79% and 95% of the area of the array. At 1.1× the emitter pitch, the lenses cover 89% of the area of the array. When emitter diameter=0.5 emitter pitch, the emitters will cover 20% of the area of the array (for square emitters).

The location of the maximum boost may be thought of as a tradeoff between competing effects. On the one hand, increasing lens diameter improves the factor by which light rays from the emitter are collimated. By the principle of conservation of etendue, d·Ω=D·Ω′, where d is the diameter of the emitter and D is the diameter of the lens. Ω is the solid angle subtended by rays leaving the emitter and Ω′ is the solid angle subtended by rays after passing through the lens. D/d is the factor by which the solid angular spread of rays is reduced by the lens. The collimating effect of the lens improves coupling into a specified acceptance angle, which increases boost.

On the other hand, as lens diameter increases in the “partial overlap” region (lens diameter between 1 and \sqrt{2} times the emitter pitch), parts of the edge of the lens are truncated. A truncated lens does not affect light rays that pass outside its edges. A larger lens collects light from a smaller solid angle as the edge of the lens is cut off where it overlaps its neighbors.

Maximum boost occurs when the beneficial effect of larger lens diameter (better collimation) is balanced by the deleterious effect of larger lens diameter (less light collected because of edge truncation).

Another potential application for arrays of micro-LEDs and microlenses is in chip-to-chip optical communication using fiber bundles. In optical fiber bundle chip-to-chip interconnects, a bundle of fibers rather than individual fibers carries optical signals. Fibers in a bundle may be closely packed in hexagonal arrays with adjacent fiber cores only a few microns apart. Each fiber bundle carries many data channels between chips. Micro-LEDs with microlenses can be used to more efficiently couple data into the fiber bundles. Alignment tolerances may be greatly relaxed when aligning a fiber bundle to an array of emitters because it is not necessary to know in advance which fiber in the bundle will be aligned with each emitter. Furthermore, it is not even necessary for the pitch or layout (e.g. square or hexagonal) of the emitter arrays to match that of the fiber cores in a fiber bundle.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. A process comprising:
creating a preform for a microlens array, the preform comprising an array of first dome shapes corresponding to microlenses in the microlens array; and
using atomic layer deposition to deposit a conformal layer on the array of first dome shapes to create an array of second dome shapes, thereby creating a master form for manufacturing the microlens array.

2. The process of claim 1 wherein the conformal layer is not thicker than 1 μm.

3. The process of claim 2 wherein a total area of the microlens array is not more than 25 um² per microlens.

4. The process of claim 1 wherein the conformal layer is not thicker than 50% of a smallest width of the first dome shapes in the preform.

5. The process of claim 1 wherein adjacent first dome shapes in the preform are not abutting, but adjacent second dome shapes in the master form are abutting with a slope-discontinuous edge at their boundary.

6. The process of claim 1 wherein adjacent first dome shapes in the preform are abutting at a slope-continuous boundary, but adjacent second dome shapes in the master form are abutting with a slope-discontinuous edge at their boundary.

7. The process of claim 1 further comprising:
creating a stamp from the master form; and
stamping the stamp into a lens material, thereby creating the microlens array.

8. The process of claim 7 wherein creating and stamping the stamp changes a shape transferred from the master form, and the master form is predistorted to compensate for the change in shape.

9. The process of claim 1 wherein creating the preform comprises:
reflowing photoresist to form shapes, and then transferring the shapes from the reflowed photoresist to silicon dioxide to create the preform.

10. The process of claim 1 wherein creating the preform comprises:
applying direct write grayscale lithography to photoresist to form shapes, and then transferring the shapes from the photoresist to silicon dioxide to create the preform.

11. A master form for manufacturing a microlens array, the master form comprising:
a preform for the microlens array, the preform comprising an array of first dome shapes corresponding to microlenses in the microlens array; and
a conformal layer deposited on the array of first dome shapes to create an array of second dome shapes.

12. The master form of claim 11 wherein the conformal layer is deposited by atomic layer deposition.

13. The master form of claim 11 wherein the conformal layer is deposited by sputtering, physical vapor deposition or chemical vapor deposition.

14. The master form of claim 11 wherein the second dome shapes abut only their nearest neighbors.

15. The master form of claim 11 wherein the preform further comprises an array of pedestals supporting the first dome shapes.

16. The master form of claim 15 wherein the array of pedestals has a pitch P, the pedestals are cylindrical with diameter D and thickness T, and D−2T<P<D.

17. The master form of claim 16 wherein P is greater than 1 μm, but less than 5 μm.

18. The master form of claim 11 wherein the second dome shapes have a fill factor of between 79% and 95%.

19. The master form of claim 11 wherein the second dome shapes have a fill factor of 100%.

20. The master form of claim 11 wherein the first dome shapes and second dome shapes are spheroidal.

21. The master form of claim 11 wherein the microlenses in the microlens array have a spherical curvature with a diameter that is between 1× and 1.2× a pitch of the microlens array.

22. The master form of claim 11 wherein the preform comprises dome shapes of different sizes and/or shapes.
